(19) United States
(12) Patent Application Publication
(10) Pub. No.: US 2018/0350940 A1
(43) Pub. Date: Dec. 6, 2018

(54) FERROELECTRIC MEMORY DEVICE

(71) Applicant: SK hynix Inc., Icheon-si (KR)

(72) Inventor: Hyangkeun YOO, Icheon-si (KR)

(21) Appl. No.: 15/975,949

(22) Filed: May 10, 2018

(30) Foreign Application Priority Data
Jun. 5, 2017 (KR) 10-2017-0069798

(51) Int. Cl. H01L 29/51; H01L 29/78; H01L 29/423; H01L 27/11585

(52) U.S. Cl. CPC H01L 29/516; H01L 29/78391; H01L 27/11585; H01L 29/4236; H01L 29/7827

(57) ABSTRACT

A ferroelectric memory device according to an embodiment includes a substrate, an interfacial insulation layer and a ferroelectric insulation layer that are sequentially disposed on an inner wall of a trench formed in the substrate. In addition, the ferroelectric memory device includes a gate electrode layer disposed on the ferroelectric insulation layer. A portion of the ferroelectric insulation layer disposed on the interfacial insulation layer common to a bottom surface of the trench and a portion of the ferroelectric insulation layer disposed on the interfacial insulation layer common to a sidewall surface of the trench have crystal growth planes in directions perpendicular to the bottom surface and the sidewall surface of the trench, respectively.

### CROSS-REFERENCE TO RELATED APPLICATION

The present application claims priority under 35 U.S.C 119(a) to Korean Patent Application No. 10-2017-0069798, filed on Jun. 5, 2017, which is herein incorporated by reference in its entirety.

### BACKGROUND

### 1. Technical Field

Various embodiments of the present disclosure generally relate to a semiconductor device, and more particularly, relate to a ferroelectric memory device.

### 2. Related Art

Generally, a ferroelectric material refers to a material having spontaneous electrical polarization in a state in which no external electric field is applied. More specifically, the ferroelectric material can maintain one of two stable remanent polarization states. Such property may be utilized to store information “0” or “1” in a nonvolatile manner.

### SUMMARY

There is disclosed a ferroelectric memory device according to an aspect of the present disclosure. The ferroelectric memory device includes a substrate, an interfacial insulation layer and a ferroelectric insulation layer that are sequentially disposed on an inner wall of a trench formed in the substrate. In addition, the ferroelectric memory device includes a gate electrode layer disposed on the ferroelectric insulation layer. A portion of the ferroelectric insulation layer disposed on the interfacial insulation layer common to a bottom surface of the trench and a portion of the ferroelectric insulation layer disposed on the interfacial insulation layer common to a sidewall surface of the trench have crystal growth planes in directions perpendicular to the bottom surface and the sidewall surface, respectively.

There is disclosed a ferroelectric memory device according to another aspect of the present disclosure. The ferroelectric memory device includes a substrate including a trench having a bottom surface and a sidewall surface, wherein the bottom surface and the sidewall surface of the trench have a crystal plane of the same family, a ferroelectric insulation layer having the same crystal growth plane on the bottom surface and the sidewall surface of the trench, and a gate electrode layer disposed on the ferroelectric insulation layer. A portion of the ferroelectric insulation layer disposed on the bottom surface of the trench has a remanent polarization orientation aligned in a direction perpendicular to the bottom surface of the trench and a portion of the ferroelectric insulation layer disposed on the sidewall surface of the trench has a remanent polarization orientation aligned in a direction perpendicular to the sidewall surface.

### BRIEF DESCRIPTION OF THE DRAWINGS

FIG. 1 is a cross-sectional view schematically illustrating a ferroelectric memory device according to an embodiment of the present disclosure.

FIG. 2 is an enlarged view of a portion of the ferroelectric memory device of FIG. 1.

FIGS. 3A and 3B are views illustrating polarization orientation of a ferroelectric insulation layer in a ferroelectric memory device according to an embodiment of the present disclosure.

FIGS. 4A to 4C are views schematically illustrating a ferroelectric memory device according to an embodiment of the present disclosure.

FIGS. 5 to 9 are views schematically illustrating a method of manufacturing a ferroelectric memory device according to an embodiment of the present disclosure.

FIGS. 10 to 15 are cross-sectional views schematically illustrating a method of manufacturing a ferroelectric memory device according to an embodiment of the present disclosure.

### DETAILED DESCRIPTION

Various embodiments will now be described hereinafter with reference to the accompanying drawings. In the drawings, the dimensions of layers and regions may be exaggerated for clarity of illustration. The drawings are described with respect to an observer's viewpoint. If an element is referred to be located on another element, it may be understood that the element is directly located on the other element, or an additional element may be interposed between the element and the other element. The same reference numerals refer to the same elements throughout the specification.

In addition, expression of a singular form of a word should be understood to include the plural forms of the word unless clearly used otherwise in the context. It will be understood that the terms “comprise” or “have” are intended to specify the presence of a feature, a number, a step, an operation, an element, a part, or combinations thereof, but not used to preclude the presence or possibility of addition one or more other features, numbers, steps, operations, components, parts, or combinations thereof. Further, in performing a method or a manufacturing method, each process constituting the method can take place differently from the stipulated order unless a specific sequence is described explicitly in the context. In other words, each process may be performed in the same manner as stated order, may be performed substantially at the same time, or may be performed in a reverse order.

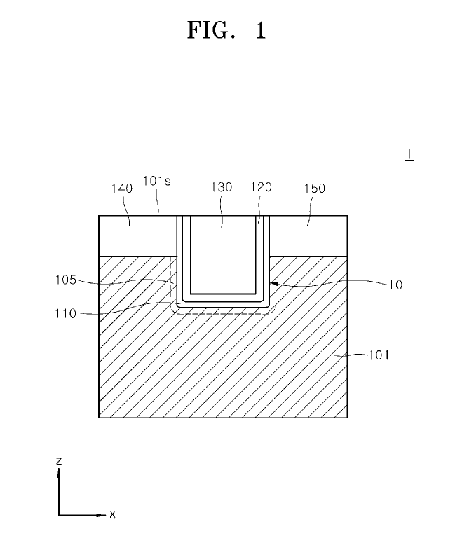

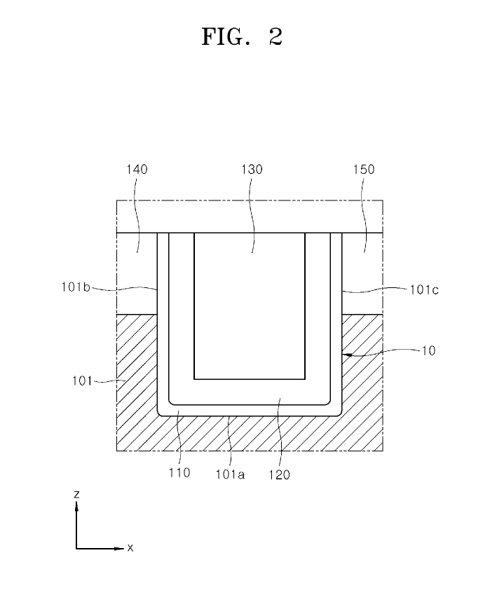

FIG. 1 is a cross-sectional view schematically illustrating a ferroelectric memory device 1 according to an embodiment of the present disclosure. FIG. 2 is an enlarged view of a portion of the ferroelectric memory device 1 of FIG. 1. The ferroelectric memory device 1 according to this embodiment may be a transistor-type memory device having a gate structure buried in a trench.

Referring to FIGS. 1 and 2, the ferroelectric memory device 1 may include a substrate 101, a ferroelectric insulation layer 120, and a gate electrode layer 130. The ferroelectric insulation layer 120 may be disposed along an inner wall surface of a trench 10 formed in the substrate 101. In addition, the ferroelectric memory device 1 may further include an interfacial insulation layer 110 disposed between the inner wall surface of the trench 10 and the ferroelectric insulation layer 120. Further, the ferroelectric memory device 1 may include a source region 140 and a drain region 150 disposed in the substrate 101 at both ends or on opposite sides of the trench 10. In an embodiment, the source and drain regions 140 and 150 may be formed by injecting a dopant into the substrate 101.

The substrate 101 may, for example, be a silicon (Si) substrate or a germanium (Ge) substrate. As another example, the substrate 101 may be a compound substrate such as a gallium arsenide (GaAs) substrate. The substrate 101 may, for example, be doped with a p-type dopant.

In an embodiment, the substrate 101 may be a single crystalline silicon substrate. At this time, a surface 101a of the single crystalline silicon substrate may be included in the set of planes {100} in a family of planes in a cubic crystal system. As an example, the surface 101s of the single crystalline silicon substrate may have a plane index of (100) of a cubic crystal system. In the present disclosure, a plane index of a crystalline structure is based on the Miller indices.

Referring to FIGS. 1 and 2, the trench 10 may be formed in the substrate 101. The trench 10 may be formed to extend from the surface 101s to an inner region of the substrate 101. The trench 10 may have a bottom surface 101a and sidewall surfaces 101b and 101c (hereinafter, for convenience of explanation, collectively referred to as “both sidewall surfaces”, as shown in the drawings). The bottom surface 101a may be substantially perpendicular to both sidewall surfaces 101b and 101c. In an embodiment, when the surface 101s of the substrate 101 has a plane index of (100) of the cubic crystal system, the bottom surface 101a of the trench 10 may also have a plane index of (100) of the cubic crystal system, and both sidewall surfaces 101b and 101c may be parallel to each other and have a plane index of (010) or (001) of the cubic crystal system. Accordingly, the bottom surface 101a and both sidewall surfaces 101b and 101c of the trench 10 may be included in the set of planes {100} in a family of a cubic crystal system.

Referring to FIGS. 1 and 2, the interfacial insulation layer 110 may be disposed along the inner wall surfaces 101a, 101b and 101c of the trench 10. The interfacial insulation layer 110 may include metal oxide. The metal oxide may, for example, have paraelectric or antiferroelectric properties. The interfacial insulation layer 110 may include, for example, zirconium oxide, hafnium oxide, or a combination thereof.

In an embodiment, the interfacial insulation layer 110 may have the same crystal system as the inner wall surfaces 101a, 101b, and 101c of the trench 10. In an embodiment, when the substrate 101 includes single crystalline silicon and the interfacial insulation layer 110 includes zirconium oxide, the interfacial insulation layer 110 may be a crystalline layer having a crystal structure of the cubic crystal system. When the bottom surface 101a of the trench 10 has a plane index of (100), a portion of the interfacial insulation layer 110 disposed on the bottom surface 101a of the trench 10 may have a plane index of (100). As an example, when both sidewall surfaces 101b and 101c of the trench 10 have a plane index of (010), portions of the interfacial insulation layer 110 disposed on sidewall surfaces 101b and 101c may also have a plane index of (010).

As described above, the interfacial insulation layer 110 may have a plane index of a {100} family of a cubic crystal system on the inner wall surfaces 101a, 101b and 101c of the trench 10. However, in an edge boundary region where the bottom surface 101a of the trench 10 meets the sidewall surfaces 101b and 101c, the interfacial insulation layer 110 may have various crystal planes different from the {100} family. The above-described crystalline interfacial insulation layer 110 may, for example, have a thickness that is equal to 1.5 nm or less, but greater than 0.

In an embodiment, the interfacial insulation layer 110 can function as a buffer layer between the substrate 101 and the ferroelectric insulation layer 120. The interfacial insulation layer 110 can reduce any difference in lattice constants between the substrate 101 and the ferroelectric insulation layer 120. In an embodiment, the interfacial insulation layer 110 may further include a dopant for changing the lattice constant thereof. As an example, when the interfacial insulation layer 110 includes zirconium oxide, the dopant may include scandium (Sc), yttrium (Y), lanthanum (La), gadolinium (Gd), actinium (Ac), or a combination of two or more thereof. In an embodiment, a silicon substrate having a plane index of {100} family of the cubic crystal system is used as the substrate 101, and hafnium oxide having a plane index of (100) of an orthorhombic crystal system is disposed as the ferroelectric insulation layer 120, then the interfacial insulation layer 110 may be an yttrium (Y)-doped zirconium oxide layer having a plane index of {100} family of the cubic crystal system. As an example, the yttrium (Y) may be doped to the zirconium oxide at a concentration of about nine (9) mole percent (mol %) to about twenty (20) mol %. Thus, the difference in lattice constant at the interface between the interfacial insulation layer 110 and the ferroelectric insulation layer 120 can be reduced.

In addition, the interfacial insulation layer 110 can function to suppress or reduce the transfer of electric charges conducted through a channel 105 in the substrate 101 from moving into the ferroelectric insulation layer 120 during a read operation of the ferroelectric memory device 1. The interfacial insulation layer 110 may also function to suppress or reduce the diffusion of materials between the substrate 101 and the ferroelectric insulation layer 120.

The ferroelectric insulation layer 120 may be disposed on the interfacial insulation layer 110. The ferroelectric insulation layer 120 may include a ferroelectric material having a remanent polarization. In operations, the remanent polarization can induce electrons in the channel region 105 in the substrate 101 located under or adjacent to the ferroelectric insulation layer 120. During a read operation of the ferroelectric memory device 1, the electrical resistance of the channel region 105 may vary depending on the amount of the electrons induced by the remanent polarization of the ferroelectric insulation layer 120.

The ferroelectric insulation layer 120 may include crystalline metal oxide. The ferroelectric insulation layer 120 may include, for example, hafnium oxide, zirconium oxide, or a combination thereof. In an embodiment, the ferroelectric insulation layer 120 may include at least one dopant. The dopant may, for example, include carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), lanthanum (La), or a combination of two or more thereof.

Meanwhile, since the interfacial insulation layer 110 is formed in a crystalline state on the inner wall surfaces 101a, 101b and 101c of the trench 10, the ferroelectric insulation layer 120 may be formed in a crystalline state on the interfacial insulation layer 110.

In an embodiment, the interfacial insulation layer 110 may be a crystalline yttrium (Y)-doped zirconium oxide layer. In the paper of “Epitaxial Y-stabilized ZrO₂ films on silicon: Dynamic growth process and interface structure” by S. J. Wang et al., published in Applied Physics Letters Vol. 80, 2541 (2002), a method of epitaxially forming an yttrium (Y)-doped zirconium oxide film on a (100) plane of a silicon wafer by pulsed laser deposition is disclosed. The yttrium (Y)-doped zirconium oxide layer formed in a thickness of 1.5 nm has a crystal structure of a cubic crystal system with a plane index of (100) on a (100) plane of the silicon wafer. A configuration of the yttrium (Y)-doped zirconium film disclosed in the above paper can be utilized as the interfacial insulation layer 110 according to an embodiment of the present disclosure. In an embodiment of the present disclosure, the yttrium (Y)-doped zirconium oxide layer may have a thickness that is equal to 1.5 nm or less, but greater than 0.

When an yttrium (Y)-doped zirconium oxide layer is implemented as the interfacial insulation layer 110, a crystalline hafnium oxide layer may be used as the ferroelectric insulation layer 120. In this embodiment, the crystalline hafnium oxide layer can be relatively easily formed on the crystalline yttrium (Y)-doped zirconium oxide layer through strain crystallization from the lattice mismatch between the layers.

In a comparative example, when an amorphous silicon oxide layer (SiO₂) is used in the interfacial insulation layer, when a hafnium oxide layer is deposited on the silicon oxide layer in a thickness of less than four (4) nm, the hafnium oxide layer preferentially forms in an amorphous state. Therefore, in order to secure a crystalline hafnium oxide layer having the thickness of less than 4 nm, the hafnium oxide layer needs to be deposited on the silicon oxide layer in a thickness of at least four (4) nm or greater, and then the thickness of the hafnium oxide layer is reduced to the desired thickness by etching the deposited hafnium oxide layer.

In contrast, in embodiments disclosed herein, a crystalline hafnium oxide layer having a thickness of about one (1) nm to about four (4) nm can be formed merely depositing hafnium oxide on the crystalline yttrium (Y)-doped zirconium oxide layer using known methods, without the need to etch back a thicker hafnium oxide layer.

In an embodiment, a portion of the ferroelectric insulation layer 120 disposed on the interfacial insulation layer 110 common to the bottom surface 101a of the trench 10 may have a crystal growth plane in a direction substantially perpendicular to the bottom surface 101a. That is, this portion of the ferroelectric insulation layer 120 may have grains grown in the direction substantially perpendicular to the bottom surface 101a. In addition, portions of the ferroelectric insulation layer 120 disposed on the interfacial insulation layer 110 common to the sidewall surfaces 101b and 101c of the trench 10 may have a crystal growth plane in a direction substantially perpendicular to the sidewall surfaces 101b and 101c. That is, portions of the ferroelectric insulation layer 120 may have grains grown in the direction substantially perpendicular to the sidewall surfaces 101b and 101c.

In an embodiment, the portion of the ferroelectric insulation layer 120 disposed on the interfacial insulation layer 110 common to the bottom surface 101a of the trench 10, and portions of the ferroelectric insulation layer 120 disposed on the interfacial insulation layer 110 common to the sidewall surfaces 101b and 101c of the trench 10 may have crystal growth planes included in the same plane index of a crystal system. As an example, when the bottom surface 101a and the sidewall surfaces 101b and 101c of the trench 10 include single crystalline silicon having a plane index of {100} family of a cubic crystal system, and the interfacial insulation layer 110 disposed on the bottom surface 101a and the sidewall surfaces 101b and 101c of the trench 10 includes zirconium oxide having a plane index of {100} family of the cubic crystal system, then the ferroelectric insulation layer 120 disposed on the interfacial insulation layer 110 may include hafnium oxide having a plane index of (100) of an orthorhombic crystal system.

Referring to FIGS. 1 and 2, the gate electrode layer 130 may be disposed on the ferroelectric insulation layer 120. The gate electrode layer 130 may be formed to fill the remainder of trench 10. The orientation of remanent polarization of the ferroelectric insulation layer 120 can thus be changed by applying a voltage to the ferroelectric insulation layer 120 through the gate electrode layer 130.

The gate electrode layer 130 may include a conductive material. The gate electrode layer 130 may include, for example, tungsten (W), titanium (Ti), copper (Cu), aluminum (Al), platinum (Pt), iridium (Ir), ruthenium (Ru), tungsten nitride, titanium nitride, tantalum nitride, iridium oxide, ruthenium oxide, tungsten carbide, titanium carbide, tungsten silicide, titanium silicide, tantalum silicide, alloys of any of the above, or a combination of two or more of the above. The gate electrode layer 130 may be composed of a single layer or a plurality of layers in the trench 10.

The source region 140 and the drain region 150 may be disposed in regions of the substrate 101 at both ends or on opposite sides of the trench 10. The source and drain regions 140 and 150 may be formed by doping the regions of the substrate 101 with a dopant of the opposite type to the substrate 101. As an example, the source and drain regions 140 and 150 may be doped with an n-type dopant.

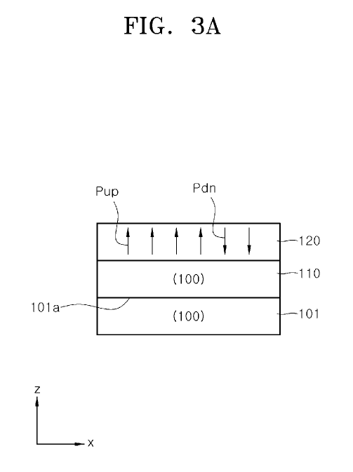

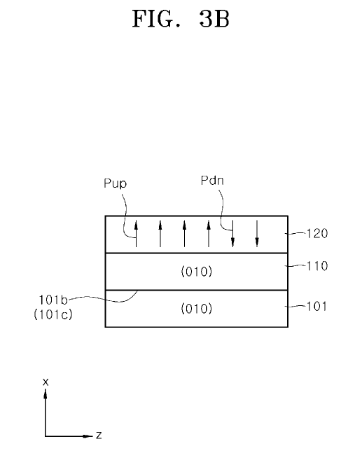

FIGS. 3A and 3B are views illustrating polarization orientation of ferroelectric insulation layer 120 in ferroelectric memory device 1 according to the embodiment of the present disclosure. FIG. 3A is a view illustrating the interfacial insulation layer 110 and the ferroelectric insulation layer 120 sequentially disposed on the bottom surface 101a of the trench 10 of the ferroelectric memory device 1 described above and with reference to FIGS. 1 and 2. FIG. 3B is a view illustrating the interfacial insulation layer 110 and the ferroelectric insulation layer 120 sequentially disposed on the sidewall surfaces 101b and 101c of the ferroelectric memory device 1.

Referring to FIG. 3A, the bottom surface 101a of the trench 10 may correspond to the (100) plane of the cubic crystal system of the single crystalline silicon substrate 101. The interfacial insulation layer 110 disposed on the bottom surface 101a may have a plane index of (100) of the cubic crystal system. The ferroelectric insulation layer 120, disposed on the interfacial insulation layer 110 having the plane index of (100), may have a plane index of (100) of the orthorhombic crystal system. As a result, after the write operation of the ferroelectric memory device 1, the ferroelectric insulation layer 120 may have remanent polarizations Pup and Pdn arranged in a direction perpendicular to the surface 101a of the single crystalline silicon substrate 101, that is, the bottom surface 101a of the trench 10.

Referring to FIG. 3B, as an example, each of the sidewall surfaces 101b and 101c of the trench 10 may correspond to the (010) plane of the cubic crystal system of the single crystalline silicon substrate 101. The interfacial insulation layer 110 disposed on the sidewall surfaces 101b and 101c may have a plane index of (010) of the cubic crystal system. The ferroelectric insulation layer 120, disposed on the interfacial insulation layer 110 having a plane index of (010), may have a plane index of (100) of the orthorhombic crystal system. As a result, after the write operation of the ferroelectric memory device 1, the ferroelectric insulation layer 120 may have remanent polarizations Pup and Pdn arranged in a direction perpendicular to the surfaces 101b and 101c—of the single crystalline silicon substrate 101, that is, the sidewall surfaces 101b and 101c of the trench 10.

As described above, the ferroelectric memory device 1 according to an embodiment of the present disclosure may be a transistor-type memory device having a buried gate electrode 130, in which the channel region 105 is formed along the trench 10 in the substrate 101. At this time, the crystal growth plane of the ferroelectric insulation layer 120 can be controlled in a direction substantially perpendicular to the inner wall surfaces 101a, 101b and 101c of the trench 10. As a result, in the write operation of the ferroelectric memory device 1, the remanent polarization orientation in the ferroelectric insulation layer 120 can be aligned in the direction perpendicular to the inner wall surfaces 101a, 101b and 101c, respectively. As an example, a portion of the ferroelectric insulation layer 120 disposed on the interfacial insulation layer 110 common to the bottom surface 101a of the trench 10 may have a remanent polarization orientation aligned in a vertical direction (z-direction) with respect to the bottom surface 101a, and portions of the ferroelectric insulation layer 120 disposed on the interfacial insulation layer 110 common to the sidewall surfaces 101b and 101c of the trench 10 may have a remanent polarization orientation aligned in a vertical direction (x direction) with respect to the sidewall surfaces 101b and 101c. Accordingly, in the write operation of the ferroelectric memory device 1 in which the channel region 105 is formed in substrate 101 along the inner wall surfaces 101a, 101b and 101c of the trench 10, the degree of alignment of the polarization orientation in the ferroelectric insulation layer 120 can be improved. The remanent polarization value of the ferroelectric insulation layer 120 after the write operation can be increased when the degree of alignment improves.

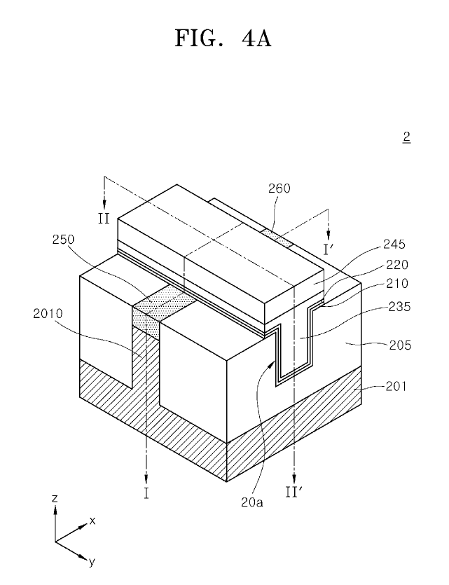

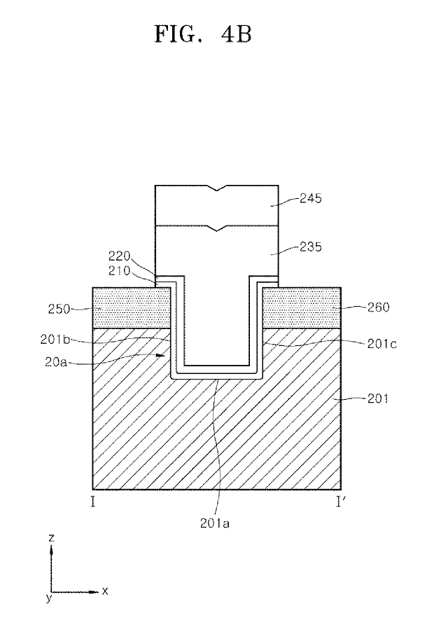

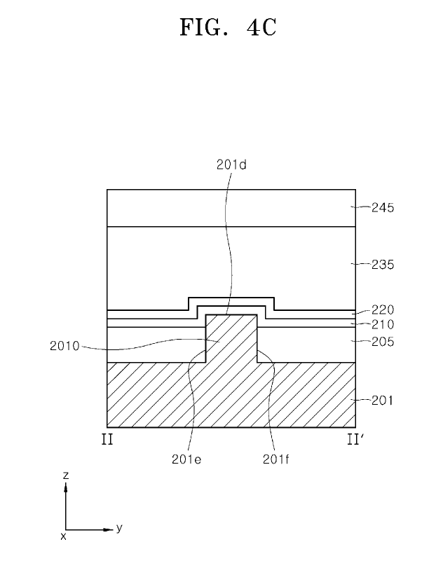

FIGS. 4A to 4C are views schematically illustrating a ferroelectric memory device 2 according to an embodiment of the present disclosure. More specifically, FIG. 4A is a perspective view of the ferroelectric memory device 2, FIG. 4B is a cross-sectional view of the ferroelectric memory device 2 taken along line I-I′ of FIG. 4A, and FIG. 4C is a cross-sectional view of the ferroelectric memory device 2 taken along line II-II′ of FIG. 4A. The ferroelectric memory device 2 illustrated in FIGS. 4A to 4C may be a three-dimensional transistor device having a saddle fin structure.

Referring to FIGS. 4A to 4C, a fin structure 2010 protrudes or extends upward from a substrate 201 in the z direction. As an example, the substrate 201 may have substantially the same configuration as the substrate 101 described above and with reference to FIG. 1. In an embodiment, the substrate 201 may be a doped single crystalline silicon substrate. In an embodiment, the fin structure 2010 may be formed of the same material as the substrate 201. The fin structure 2010 may be arranged along an x direction.

Referring to FIGS. 4A and 4C, an insulation layer 205 may be disposed surrounding the fin structure 2010 on the substrate 201. At this time, a top surface of the fin structure 2010 and an upper surface of the insulation layer 205 may be positioned on the same plane.

Referring to FIGS. 4A and 4B, an interfacial insulation layer 210 may be disposed along inner walls 201a, 201b and 201c of a first trench 20a formed in the saddle fin structure 2010. A ferroelectric gate insulation layer 220 may be disposed on the interfacial insulation layer 210.

Referring to FIG. 4B, the inner walls 201a, 201b and 201c of the first trench 20a may be composed of a bottom surface 201a and sidewall surfaces 201b and 201c. In an embodiment, the bottom surface 201a of the first trench 20a may have a plane index of (100) of a cubic crystal system, and the sidewall surfaces 201b and 201c parallel to each other and have a plane index of (010) or (001). Accordingly, the bottom surface 201a and sidewall surfaces 201b and 201c of the first trench 20a may each have a plane included in the set of planes {100} in a family of the cubic crystal system.

The interfacial insulation layer 210 may disposed along the inner walls 201a, 201b and 201c of the first trench 20a. A configuration of the interfacial insulation layer 210 may be substantially the same as a configuration of the interfacial insulation layer 110 disposed along the inner walls 101a, 101b and 101c of the trench 10 described above and with reference to FIGS. 1 and 2. The interfacial insulation layer 210 may have a plane index of a {100} family of the cubic crystal system on the inner walls 201a, 201b and 201c of the first trench 20a. However, in some embodiments, in an edge boundary region where the bottom surface 201a of the first trench 20a meets the sidewall surfaces 201b and 201c, the interfacial insulation layer 210 may have various other crystal planes having different plane index from the {100} family. The above-described crystalline interfacial insulation layer 210 may have a thickness that is equal to 1.5 nm or less, but greater than 0, for example.

The ferroelectric gate insulation layer 220 may be disposed on the interfacial insulation layer 210. A configuration of the ferroelectric gate insulation layer 220 may be substantially the same as a configuration of the ferroelectric insulation layer 120 disposed on the inner wall surfaces 101a, 101b and 101c of the trench 10 described above and with reference FIGS. 1 and 2.

In other words, a portion of the ferroelectric gate insulation layer 220 disposed on the interfacial insulation layer 210 common to the bottom surface 201a of the first trench 20a may have a crystal growth plane in a direction substantially perpendicular to the bottom surface 201a of the first trench 20a. That is, the portion of the ferroelectric gate insulation layer 220 may have grains grown substantially in the z-direction. In addition, portions of the ferroelectric gate insulation layer 220 disposed on the interfacial insulation layer 210 common to the sidewall surfaces 201b and 201c of the first trench 20a may have a crystal growth plane in a direction substantially perpendicular to the sidewall surfaces 201b and 201c. That is, the portion of the ferroelectric gate insulation layer 220 may have grains grown substantially in the x-direction.

In an embodiment, the portion of the ferroelectric gate insulation layer 220 disposed on the interfacial insulation layer 210 common to the bottom surface 201a of the first trench 20a and portions of the ferroelectric gate insulation layer 220 disposed on the interfacial insulation layer 210 common to the sidewall surfaces 201b and 201c of the first trench 20a may have crystal growth planes included in the same plane index of a crystal system.

As an example, when the bottom surface 201a and the sidewall surfaces 201b and 101c of the first trench 20a include single crystal silicon having a plane index of {100} family of a cubic crystal system, and the interfacial insulation layer 210 disposed on the bottom surface 201a and the sidewall surfaces 201b and 201c includes zirconium oxide having a plane index of {100} family of the cubic crystal system, the ferroelectric insulation layer 220 disposed on the interfacial insulation layer 210 may include a plane index of (100) of an orthorhombic crystal system. However, in some embodiments, in an edge boundary region where the bottom surface 201a of the first trench 20a meets the sidewall surfaces 201b and 201c, the portion of the ferroelectric insulation layer 220 may have various crystal planes having plane indices different from those of the above-described (100) plane of an orthorhombic system.

Referring to FIG. 4C, the interfacial insulation layer 210 and the ferroelectric gate insulation layer 220 may be disposed on at least a portion of the top surface 201d and both side surfaces 201e and 201f of the fin structure 2010. In an embodiment, the top surface 201d may have a plane index of (100) of a cubic crystal system. The side surfaces 201e and 201f may have a plane index of (010) or (001) of a cubic crystal system. The interfacial insulation layer 210 may have a plane index of {100} family of a cubic crystal system on the top surface 201d and both side surfaces 201e and 201f. However, in some embodiments, a portion of the interfacial insulation layer 210 in the edge boundary regions where the top surface 201d meets the side surfaces 201e and 201f may have various crystal planes having plane indices different from those of the above-described plane (100) of a cubic crystal system.

In an embodiment, the ferroelectric gate insulation layer 220 may have a plane index of (100) of an orthorhombic crystal system on the interfacial insulation layer 210. At this time, a portion of the ferroelectric gate insulation layer 220 disposed on the interfacial insulation layer 210 common to the top surface 201d of the fin structure 2010 may have a crystal growth plane in a direction substantially perpendicular to the top surface 201d. Portions of the ferroelectric insulation layer 220 disposed on the interfacial insulation layer 210 common to the side surfaces 201e and 201f of the fin structure 2010 may have a crystal growth plane in a direction substantially perpendicular to the side surfaces 201e and 201f. However, in some embodiments, in edge boundary regions where the top surface 201d meets the side surfaces 201e and 201f, the portion of the ferroelectric insulation layer 220 may have various crystal planes having plane indices different from those of the above-described (100) plane of an orthorhombic crystal system.

Referring to FIGS. 4A to 4C, a gate electrode layer 235 and an upper conductive layer 245 may be sequentially disposed on the ferroelectric gate insulation layer 220. The gate electrode layer 235 and the upper conductive layer 245 may be arranged along a y-direction. The gate electrode layer 235 and the upper conductive layer 245 may constitute a word line.

A configuration of the gate electrode layer 235 may be substantially the same as a configuration of the gate electrode layer 130 of the embodiment described above and with reference to FIGS. 1 and 2. The upper conductive layer 245 may, for example, be formed of a metal material. The upper conductive layer 245 may have a lower electrical resistance than the gate electrode layer 235. The upper conductive layer 245 may include, for example, copper (Cu), aluminum (Al), tungsten (W) or the like.

A source region 250 and a drain region 260 may be disposed in regions of the substrate 201 at both ends or on opposite sides of the gate electrode layer 235. The source and drain regions 250 and 260 may be formed by doping the regions of the substrate 201 with a doping type opposite to a doping type of the substrate 201. As an example, the source and drain regions 250 and 260 may be doped with an n-type dopant.

As described above, the ferroelectric memory device 2 of this embodiment may have the interfacial insulation layer 210 and the ferroelectric gate insulation layer 220 disposed on the inner wall surfaces 201a, 201b and 201c of the first trench 20a and on the wall surfaces 201d, 201e and 201f of a transistor having a saddle fin structure.

At this time, by controlling the crystal growth plane of the ferroelectric gate insulation layer 220 in the substantially vertical direction with respect to the inner wall surfaces 201a (z direction), 201b and 201c (x direction) of the first trench 20a and the wall surfaces 201d (z direction), 201e and 201f (y direction) of the fin structure 2010, the remanent polarization orientation in the ferroelectric gate insulation layer 220 can be aligned perpendicular with respect to the inner wall surfaces 201a, 201b and 201c and wall surfaces 201d, 201e and 201f in the write operation of the ferroelectric memory device 2. As a result, in the write operation of the ferroelectric memory device 2, the degree of alignment of the polarization orientation in the ferroelectric gate insulation layer 220 can be improved. When the degree of alignment of the polarization orientation is improved, the remanent polarization value of the ferroelectric gate insulation layer 220 can be increased after the write operation.

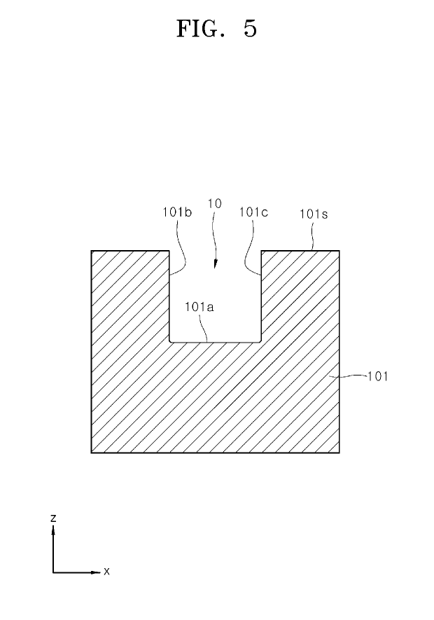

FIGS. 5 to 9 are views schematically illustrating a method of manufacturing a ferroelectric memory device according to an embodiment of the present disclosure.

Referring to FIG. 5, a substrate 101 may be prepared. As an example, the substrate 101 may include a semiconductor material. In an embodiment, the substrate 101 may be a p-type doped silicon substrate. A surface 101s of the substrate 101 may have a plane index of (100) of a cubic crystal system.

A trench 10 may be formed in the substrate 101. The trench 10 may be formed from the surface 101s of the substrate 101 to an inner region. In an embodiment, the trench 10 may be formed by selectively patterning the substrate 101 using an anisotropic etching method. The trench 10 may have a bottom surface 101a and sidewall surfaces 101b and 101c. The bottom surface 101a and the sidewall surfaces 101b and 101c may be substantially perpendicular to each other. In an embodiment, the patterning may proceed so that the bottom surface 101a of the trench 10 may have a plane index of (100) of a cubic crystal system, and the sidewall surfaces 101b and 101c parallel to each other may have a plane index of (010) or (001) of a cubic crystal system.

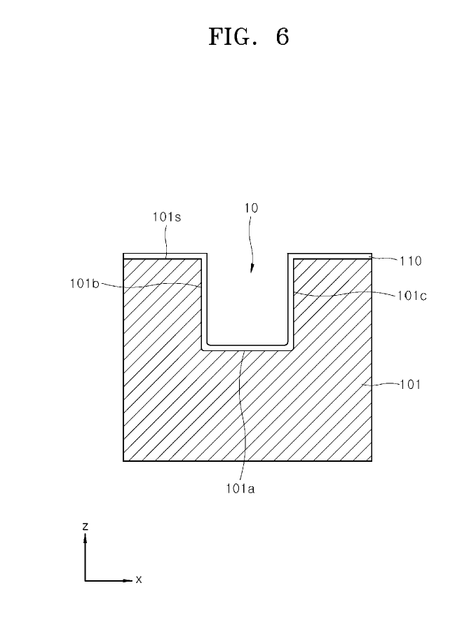

Referring to FIG. 6, an interfacial insulation layer 110 may be formed along the inner wall surfaces 101a, 101b and 101c of the trench 10 and the surface 101s of the substrate 101. The interfacial insulation layer 110 may include crystalline metal oxide. As an example, the interfacial insulation layer 110 may include zirconium oxide, hafnium oxide, or a combination thereof. The interfacial insulation layer 110 may function as a buffer layer between the inner wall surfaces 101a, 101b and 101c and a ferroelectric insulation layer 120 to be formed later.

In an embodiment, the interfacial insulation layer 110 may include a dopant to adjust a lattice constant of the interfacial insulation layer 110. The dopant may include, for example, scandium (Sc), yttrium (Y), lanthanum (La), gadolinium (Gd), actinium (Ac) or a combination of two or more thereof.

The interfacial insulation layer 110 may, for example, be formed by applying a chemical vapor deposition method, an atomic layer deposition method or the like. The dopant may be injected as a source gas during the deposition of the interfacial insulation layer 110, or may be injected by ion implantation or the like after deposition of the interfacial insulation layer 110.

The interfacial insulation layer 110 may be formed in a crystalline state. The interfacial insulation layer 110 may have, for example, a thickness that is equal to 1.5 nm or less, but greater than 0. In an embodiment, when a silicon substrate having a plane index of {100} family of a cubic crystal system is used as the substrate 101 and a hafnium oxide layer having a plane index of (100) of an orthorhombic crystal system is utilized as the ferroelectric insulation layer 120, the interfacial insulation layer 110 may be formed with an yttrium (Y)-doped zirconium oxide layer having a plane index of {100} family of a cubic crystal system. As an example, the yttrium (Y) may be doped to the zirconium oxide layer at a concentration of nine (9) mol % to twenty (20) mol %. In an embodiment, the yttrium (Y)-doped zirconium oxide layer having the plane index of {100} family may be obtained by a sufficiently low deposition rate when the interfacial insulation layer 110 is formed on the silicon substrate using the chemical vapor deposition method or the atomic layer deposition.

In an embodiment, when the bottom surface 101a of the trench 10 has a plane index of (100), a portion of the interfacial insulation layer 110 disposed on the bottom surface 101a may have a plane index of (100). In addition, when the sidewall surfaces 101b and 101c of the trench 10 have a plane index of (010), portions of the interfacial insulation layer 110 disposed on the sidewall surfaces 101b and 101c may have a plane index of (010).

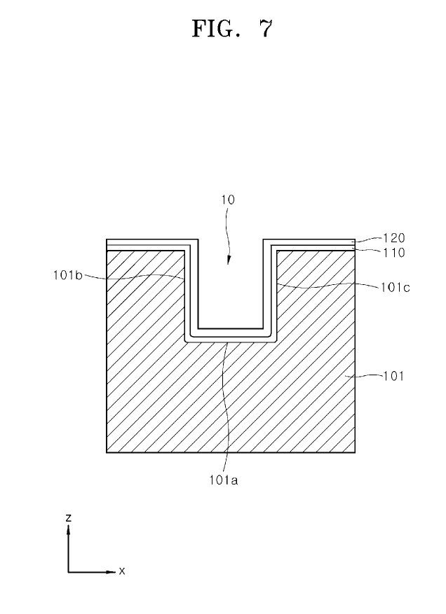

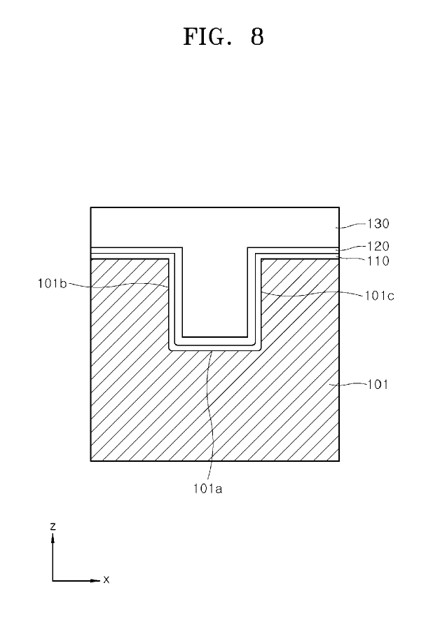

Referring to FIG. 7, the ferroelectric insulation layer 120 may be formed on the interfacial insulation layer 110. The ferroelectric insulation layer 120 may include a ferroelectric material having a remanent polarization. The ferroelectric insulation layer 120 may include, for example, hafnium oxide, zirconium oxide, or a combination thereof. In an embodiment, the ferroelectric insulation layer 120 may include at least one dopant. The dopant may include, for example, carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), lanthanum (La) or a combination of two or more thereof.

In an embodiment, the ferroelectric insulation layer 120 may, for example, be formed by applying a chemical vapor deposition method, an atomic layer deposition method or the like. The ferroelectric insulation layer 120 may, for example, be formed in a thickness of about one (1) nm to about four (4) nm.

In an embodiment, a portion of the ferroelectric insulation layer 120 disposed on the interfacial insulation layer 110 common to, the bottom surface 101a of the trench 10 may be formed to have a crystal growth plane in a direction substantially perpendicular to the bottom surface 101a. Portions of the ferroelectric insulation layer 120 disposed on the interfacial insulation layer 110 common to the sidewall surfaces 101b and 101c of the trench 10 may be formed to have a crystal growth plane in a direction substantially perpendicular to the sidewall surfaces 101b and 101c.

In an embodiment, when a silicon (Si) substrate having a plane index of {100} family of a cubic crystal system is used as the substrate 101 and an yttrium (Y)-doped zirconium oxide layer having a plane index of {100} family of a cubic crystal system is utilized as the interfacial insulation layer 110, the ferroelectric insulation layer 120 may be formed with a hafnium oxide layer having a plane index of (100) of an orthorhombic crystal system. In an embodiment, the hafnium oxide layer having a plane index of (100) of an orthorhombic crystal system may be obtained by a sufficiently low deposition rate when the ferroelectric insulation layer 120 is formed on the interfacial insulation layer 110 using the chemical vapor deposition method or the atomic layer deposition.

Referring to FIG. 8, a gate electrode layer 130 may be formed on the ferroelectric insulation layer 120 in the trench 10. At this time, the gate electrode layer 130 may be formed to fill the remainder of the trench 10. The gate electrode layer 130 may be deposited on the ferroelectric insulation layer 120 outside the trench 10.

The gate electrode layer 130 may include, for example, tungsten (W), titanium (Ti), copper (Cu), aluminum (Al), platinum (Pt), iridium (Ir), ruthenium (Ru), tungsten nitride, titanium nitride, tantalum nitride, iridium oxide, ruthenium oxide, tungsten carbide, titanium carbide, tungsten silicide, titanium silicide, tantalum silicide, or a combination of two or more thereof. The gate electrode layer 130 may, for example, be formed using a chemical vapor deposition method, an atomic layer deposition method, or a sputtering method.

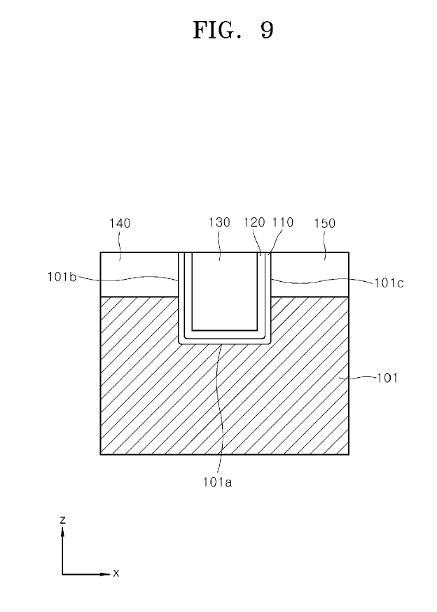

Referring to FIG. 9, the gate electrode layer 130, the ferroelectric insulation layer 120, the interfacial insulation layer 110 disposed outside the trench 10 may be removed by performing a planarization process or a selective etching process. The removal process may be performed until the surface of the substrate 101 outside the trench 10 is exposed.

Next, a source region 140 and a drain region 150 may be formed in substrate 101 regions at both ends or on opposite sides of the trench 10. The source and drain regions 140 and 150 may be formed by selectively injecting an n-type dopant into the substrate 101. The dopant may be injected, for example, using an ion implantation method.

By progressing through the above-described processes, a ferroelectric memory device according to an embodiment of the present disclosure can be manufactured. The ferroelectric memory device to be manufactured may be substantially the same as the ferroelectric memory device 1 described above and with reference to FIGS. 1 and 2.

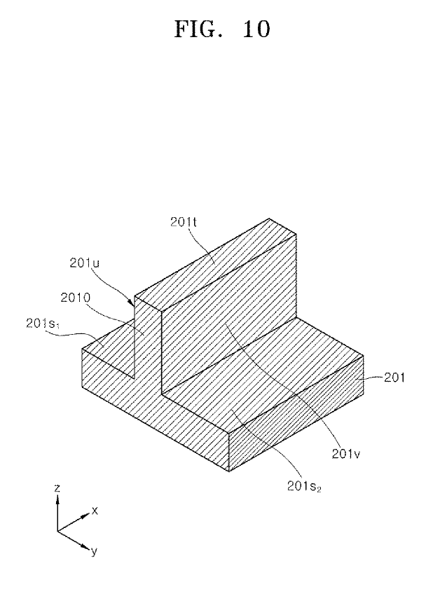

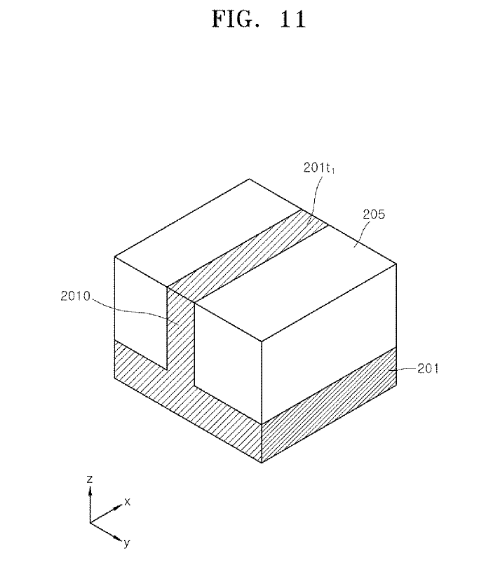

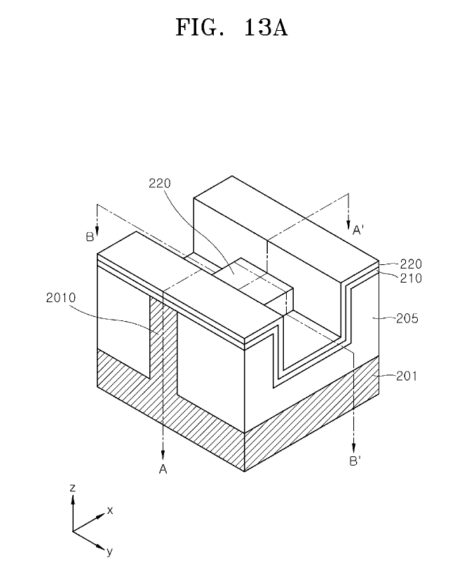

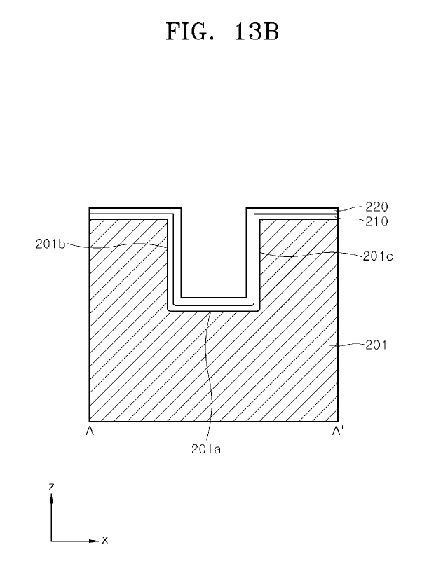

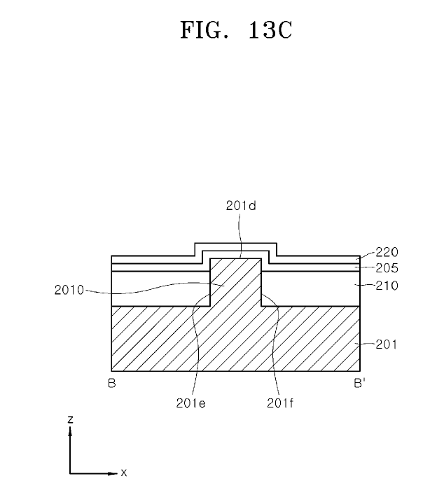

FIGS. 10 to 14 are cross-sectional views schematically illustrating a method of manufacturing a ferroelectric memory device according to an embodiment of the present disclosure. FIGS. 13B and 13C are cross-sectional views taken along line A-A′ and line B-B′, respectively, of the perspective view of FIG. 13A.

Referring to FIG. 10, a substrate 201 may be prepared. As an example, the substrate 201 may include a semiconductor material. In an embodiment, the substrate 201 may be a p-type doped silicon substrate.

Next, the substrate 201 may be selectively etched by an anisotropic etching to form a fin structure 2010 that protrudes or extends from an upper portion of the substrate 201. After anisotropic etching, the substrate 201 may have a first surface 201s1 and a second surface 201s2. The fin structure 2010 may have a top surface 201ₜ and both side surfaces 201u and 201v. In an embodiment, the first and second surfaces 201s1 and 201s2 and the top surface 201t may have a plane index of (100) of a cubic crystal system and the side surfaces 201u and 201v, which are parallel to each other, may have a plane index of (001) of the cubic crystal system.

Referring to FIG. 11, an insulation layer 205 surrounding the fin structure 2010 on the substrate 201 may be formed. At this time, the insulation layer 205 may be planarized such that the upper surface of the fin structure 2010 and the upper surface of the insulation layer 205 are positioned on the same plane. The insulation layer 205 may be formed by applying a chemical vapor deposition method, a coating method or the like. The insulation layer 205 may be planarized, for example, by applying a chemical mechanical polishing process or an etch-back process.

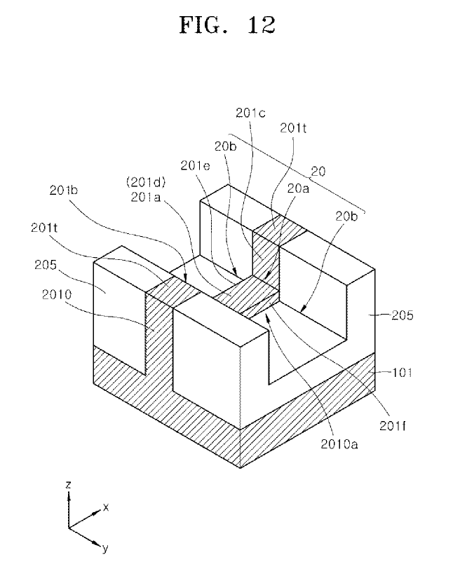

Referring to FIG. 12, the fin structure 2010 and the insulation layer 205 may be etched to form a trench 20. In a specific embodiment, the fin structure 2010 may be selectively etched to form a first trench 20a. Also, the insulation layer 205 may be selectively etched to form second trenches 20b. At this time, the etching depth for the insulation layer 205 may be greater than the etching depth of the fin structure 2010. As a result, a fin recess region 2010a, which is a region protruding upward from the substrate 201 in the trench 20, may be formed.

In the recess region 2010a, the fin structure 2010 may have a bottom surface 201a and both sidewall surfaces 201b and 201c. In addition, the fin structure 2010 may have an upper surface 201d and both sidewall surfaces 201e and 201f formed by the second trenches 20b. As illustrated, the bottom surface 201a of the first trench 20a and the upper surface 201d of the fin structure 2010 are the same plane.

In an embodiment, the bottom surface 201a of the first trench 20a and the upper surface 201d of the fin structure 2010 may have a plane index of (100) of a cubic crystal system. The sidewall surfaces 201b and 201c of the first trench 20a may have a plane index of (010) of the cubic crystal system. The side surfaces 201e and 201f of the fin structure 2010 may have a plane index of (001) of the cubic crystal system.

Referring to FIGS. 13A and 13B, an interfacial insulation layer 210 may be formed on the fin recess region 2010a along the inner wall surfaces 201a, 201b and 201c of the first trench 20a. As illustrated in FIGS. 13A and 13C, the interfacial insulation layer 210 may be formed on the upper surface 201d and side surfaces 201e and 201f near the fin recess region 2010a. In an embodiment, the interfacial insulation layer 210 may be formed in a crystalline state using a chemical vapor deposition method or an atomic layer deposition method, for example. The interfacial insulation layer 210 may be formed in a sufficiently low deposition rate to obtain a crystal structure. The interfacial insulation layer 210 may be formed to have a thickness that is equal to 1.5 nm or less, but greater than 0, for example. As an example, the interfacial insulation layer 210 may include zirconium oxide, hafnium oxide, or a combination thereof. The interfacial insulation layer 210 may include a dopant to adjust a lattice constant of the interfacial insulation layer 210. The dopant may include, for example, scandium (Sc), yttrium (Y), lanthanum (La), gadolinium (Gd), actinium (Ac) or a combination of two or more thereof.

The interfacial insulation layer 210 may have substantially the same plane index as the inner wall surfaces 201a, 201b and 201c of the first trench 20a, and the upper surface 201d and side surfaces 201e and 201f of the fin recess region 2010a. In an embodiment, the interfacial insulation layer 210 may have a plane index of {100} family of a cubic crystal system.

Referring to FIGS. 13A and 13C, a ferroelectric insulation layer 220 may be formed on the interfacial insulation layer 210. The ferroelectric insulation layer 220 may be formed in a crystalline state using a chemical vapor deposition method or an atomic layer deposition method, for example. In an embodiment, ferroelectric insulation layer 220 may be formed in a sufficiently low deposition rate to obtain a crystal structure. The ferroelectric insulation layer 220 may be formed to have a thickness about one (1) nm to about four (4) nm, for example.

The ferroelectric insulation layer 220 may be formed to have a crystal growth plane in a direction perpendicular to the inner wall surfaces 201a, 201b and 201c of the first trench 20a under the ferroelectric insulation layer 220 and to the upper surface 201d and side surfaces 201e and 201f of the fin recess region 2010a. In an embodiment, the ferroelectric insulation layer 220 may have a plane index of (100) of an orthorhombic system.

The ferroelectric insulation layer 220 may include, for example, hafnium oxide, zirconium oxide, or a combination thereof. In an embodiment, the ferroelectric insulation layer 220 may include at least one dopant. The dopant may include, for example, carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), lanthanum (La) or a combination of two or more thereof.

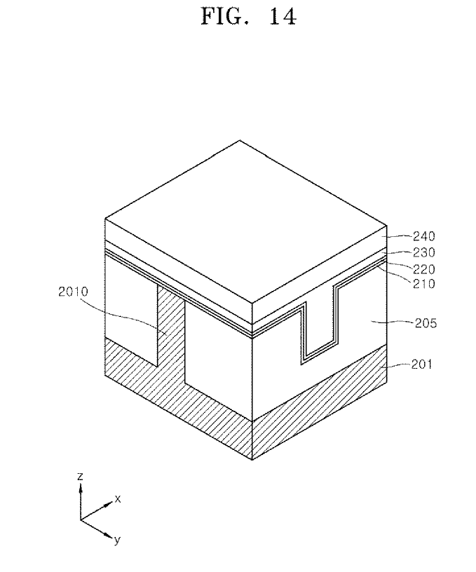

Referring to FIG. 14, a gate electrode layer 230 and an upper conductive layer 240 may be sequentially formed on the ferroelectric insulation layer 220. The gate electrode layer 230 may include, for example, tungsten (W), titanium (Ti), copper (Cu), aluminum (Al), platinum (Pt), iridium (Ir), ruthenium (Ru), tungsten nitride, titanium nitride, tantalum nitride, iridium oxide, ruthenium oxide, tungsten carbide, titanium carbide, tungsten silicide, titanium silicide, tantalum silicide, alloys of any of the above, or a combination of two or more of the above. The gate electrode layer 230 may be formed using a chemical vapor deposition method, an atomic layer deposition method or a sputtering method, for example. The upper conductive layer 240 may be formed of a metal material, for example. In an embodiment, the upper conductive layer 240 may have a lower electrical resistance than the gate electrode layer 230. The upper conductive layer 240 may include, for example, copper (Cu), aluminum (Al), tungsten (W) or the like. The upper conductive layer 240 may, for example, be formed using a chemical vapor deposition method, an atomic layer deposition method or a sputtering method.

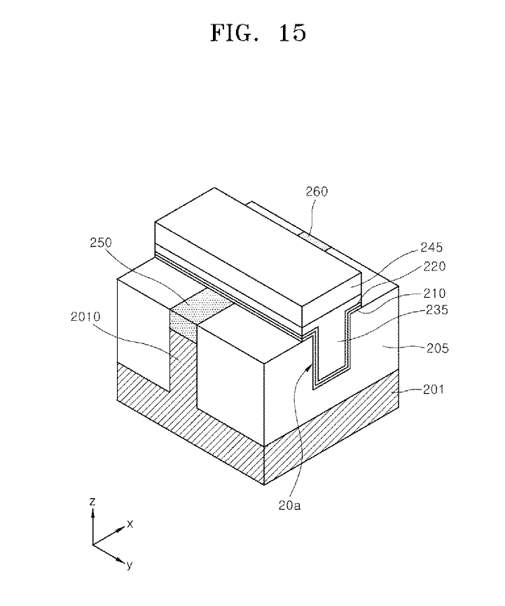

Referring to FIG. 15, the gate electrode layer 230 and the upper conductive layer 240 may be selectively etched to form a gate electrode layer 235 and an upper conductive layer 245. Next, the fin structure 2010 positioned at both ends or opposite sides of the gate electrode layer 235 may be doped to form a source region 250 and a drain region 260. The source and drain regions 250 and 260 may be formed by selectively injecting an n-type dopant into the fin structure 2010. The dopant injecting may be performed using an ion implantation method, for example.

By proceeding through the above-described processes, a ferroelectric memory device according to an embodiment of the present disclosure can be manufactured. The ferroelectric memory device to be manufactured may be substantially the same as the ferroelectric memory device 2 described above and with reference to FIGS. 4A to 4C.

The embodiments of the inventive concept have been disclosed above for illustrative purposes. Those of ordinary skill in the art will appreciate that various modifications, additions and substitutions are possible, without departing from the scope and spirit of the inventive concept as disclosed in the accompanying claims.

What is claimed is:

1. A ferroelectric memory device comprising:
a substrate;
an interfacial insulation layer and a ferroelectric insulation layer that are sequentially disposed on an inner wall surface of a trench formed in the substrate; and
a gate electrode layer disposed on the ferroelectric insulation layer,
wherein a portion of the ferroelectric insulation layer disposed on the interfacial insulation layer common to a bottom surface of the trench and a portion of the ferroelectric insulation layer disposed on the interfacial insulation layer common to a sidewall surface of the trench have crystal growth planes in directions perpendicular to the bottom surface and the sidewall surface, respectively.

2. The ferroelectric memory device of claim 1, wherein the portion of the ferroelectric insulation layer disposed on the interfacial insulation layer common to the bottom surface of the trench and the portion of the ferroelectric insulation layer disposed on the interfacial insulation layer common to the sidewall surface of the trench have the crystal growth plane included in the same plane index of a crystal system.

3. The ferroelectric memory device of claim 2,
wherein the bottom surface and the sidewall surface of the trench have a plane index of {100} family of a cubic crystal system, and
the ferroelectric insulation layer has a plane index of (100) of an orthorhombic crystal system.

4. The ferroelectric memory device of claim 1,
wherein the interfacial insulation layer has a plane index of {100} family of a cubic crystal system.

5. The ferroelectric memory device of claim 1,
wherein the portion of the ferroelectric insulation layer disposed on the interfacial insulation layer common to the bottom surface of the trench has a remanent polarization orientation aligned in a direction perpendicular to the bottom surface of the trench, and
the portion of the ferroelectric insulation layer disposed on the sidewall surface of the trench has a remanent polarization orientation aligned in a direction perpendicular to the sidewall surface of the trench.

6. The ferroelectric memory device of claim 1,
wherein the interfacial insulation layer comprises crystalline metal oxide.

7. The ferroelectric memory device of claim 1,
wherein the substrate comprises single crystalline silicon, the interfacial insulation layer comprises zirconium oxide, and the ferroelectric insulation layer comprises hafnium oxide.

8. The ferroelectric memory device of claim 7,
wherein the zirconium oxide comprises at least one of scandium (Sc), yttrium (Y), lanthanum (La), gadolinium (Gd) and actinium (Ac) as a dopant.

9. The ferroelectric memory device of claim 7,
wherein ferroelectric insulation layer has a thickness of 1 nm to 4 nm.

10. The ferroelectric memory device of claim 1,
wherein the gate electrode layer comprises at least one selected from the group consisting of tungsten (W), titanium (Ti), copper (Cu), aluminum (Al), platinum (Pt), iridium (Ir), ruthenium (Ru), tungsten nitride, titanium nitride, tantalum nitride, iridium oxide, ruthenium oxide, tungsten carbide, titanium carbide, tungsten silicide, titanium silicide, and tantalum silicide.

11. The ferroelectric memory device of claim 1,
further comprising a source region and a drain region disposed in the substrate on opposite sides of the trench.

12. A ferroelectric memory device comprising:
a substrate including a trench formed therein having a bottom surface and a sidewall surface, wherein the bottom surface and the sidewall surface of the trench have a crystal plane of the same family;
a ferroelectric insulation layer having the same crystal growth plane on the bottom surface and the sidewall surface of the trench; and
a gate electrode layer disposed on the ferroelectric insulation layer,
wherein a portion of the ferroelectric insulation layer disposed on the bottom surface of the trench has a remanent polarization orientation aligned in a direction perpendicular to the bottom surface of the trench, and
a portion of the ferroelectric insulation layer disposed on the sidewall surface of the trench has a remanent polarization orientation aligned in a direction perpendicular to the sidewall surface of the trench.

13. The ferroelectric memory device of claim 12,
wherein the portion of the ferroelectric insulation layer disposed on the bottom surface of the trench and the portion of the ferroelectric insulation layer disposed on the sidewall surface of the trench have crystal growth planes in directions perpendicular to the bottom surface and the sidewall surface of the trench, respectively.

14. The ferroelectric memory device of claim 12, further comprising a crystalline buffer layer disposed between the bottom surface and sidewall surface of the trench and the ferroelectric insulation layer.

15. The ferroelectric memory device of claim 14,
wherein the crystalline buffer layer comprises metal oxide.

16. The ferroelectric memory device of claim 14,
wherein the crystalline buffer layer comprises zirconium oxide doped with a dopant, and the ferroelectric insulation layer comprises hafnium oxide, the dopant comprising one of scandium (Sc), yttrium (Y), lanthanum (La), gadolinium (Gd) and actinium (Ac) as a dopant.

17. The ferroelectric memory device of claim 14,
wherein ferroelectric insulation layer has a thickness of 1 nm to 4 nm.

18. The ferroelectric memory device of claim 14,
wherein the bottom surface and the sidewall surface of the trench have a plane index of {100} family of a cubic crystal system,
the crystalline buffer layer has a plane index of {100} family of a cubic crystal system on the bottom surface and the sidewall surface of the trench, and
the ferroelectric insulation layer has a plane index of (100) of an orthorhombic crystal system.

19. The ferroelectric memory device of claim 12,
wherein the gate electrode layer comprises at least one selected from the group consisting of tungsten (W), titanium (Ti), copper (Cu), aluminum (Al), platinum (Pt), iridium (Ir), ruthenium (Ru), tungsten nitride, titanium nitride, tantalum nitride, iridium oxide, ruthenium oxide, tungsten carbide, titanium carbide, tungsten silicide, titanium silicide, and tantalum silicide.

20. The ferroelectric memory device of claim 12,
further comprising a source region and a drain region disposed in the substrate at opposite ends of the trench.
